(19) United States
(12) Patent Application Publication
(10) Pub. No.: US 2002/0019168 A1
(43) Pub. Date: Feb. 14, 2002

(54) PIN ARRAY HEADER WITH FLOATING SURFACE MOUNT INTERCONNECTS

(76) Inventors: ROBERT W. HOOLEY, SCOTTSDALE, AZ (US); LARRY G. SANDERS, CAMPBELL, CA (US); REX W. KELLER, GLENDALE, AZ (US)

Correspondence Address: MICHAEL J SWOPE, WOODCOCK WASHBURN KURTZ, MACKIEWICZ & NORRIS, ONE LIBERTY PLACE 46TH FLOOR, PHILADELPHIA, PA, 19103

(21) Appl. No.: 09/228,848

(22) Filed: Jan. 12, 1999

(51) Int. Cl. H05K 1/00

(52) U.S. Cl. 439/625

(57) ABSTRACT

A floating terminal connector for use with a circuit substrate having a plurality of elongated conductors. A pin retention structure is axially aligned with through holes on a connector body. A terminal pin passes through the through hole and pin retention structure. An annular projection on the terminal provides a stop to the float travel of the terminal pin in one direction. A head on the terminal pin stops float travel of the terminal pin in the opposite direction.

### BACKGROUND OF THE INVENTION

1. Field of the Invention

The present invention relates to electrical connectors and more particularly to high density pin grid array (PGA) adapters.

2. Brief Description of Prior Developments

The drive to reduce the size of electronic equipment and to add additional functions to such equipment has resulted in increasing circuit densities. The increasing circuit densities along with added functionality has in turn required multi-pin electrical connectors with reductions in the pitch between terminal pins, so that a relatively high number of terminals fit within tightly circumscribed areas that are allotted for receiving connectors on printed circuit boards and other circuit substrates.

In some arrangements, the terminal pins of multi-pin connectors have tails which are inserted in through holes in printed circuit boards and soldered to electrical traces to create an electrical contact between the board and the connector. In other arrangements, terminal pins are soldered directly to the surface of a printed circuit board (PCB) using so-called surface mounting technology.

The high terminal pin densities have made terminal pin soldering more difficult, particularly in the case of surface mounting of the terminal pins to a printed circuit board. If there is a lack of coplanarity between the connector and the printed circuit board to which it is to be attached, some of the solder joints between the terminal pins and the PCB may not be satisfactory. As a result, reliability of the connector to circuit board connection may suffer.

Floating terminal pins have been proposed to allow the connector to adjust to any irregularities between the connector and the circuit board, such as the coplanarity described above. Other floating terminal pins have used a through hole in a connector body with a diameter about the size of the main terminal pin body. Because the through hole had to accommodate both the terminal pin and a stop that was typically pushed through the through hole during assembly such designs typically had poor dimensional tolerances. In an attempt to stabilize the pin within the through hole, some designs employed barbs along the length of the terminal pin. However, the use of barbs has had a side effect of generating debris that either contaminates the connector or requires additional cleaning costs or both.

### SUMMARY OF THE INVENTION

It is an object of the present invention to provide a floating terminal pin connector system that has tolerances within acceptable manufacturing practices while providing advantages for positioning the terminal pins both within a connector body and relative to the electrical connection pads of a printed circuit board or electrical component to which it is attached.

According to an aspect of the invention, the connector comprises a terminal pin through hole with an increased length over diameter ratio that significantly improves the true position of the terminal pins.

According to another aspect of the invention, the terminal pin of the connector employs a piston-like movement within the through holes to eliminate uncertainty of the terminal pin relative to the electrical connection pads of the circuit substrate to which it is attached.

According to a further aspect of the present invention manufacturing advantages are obtained by a pin insertion method and structure that requires minimal force to insert a terminal pin into a through hole while providing significant resistance to removal of the pin once it inserted.

The invention meets the above needs by providing an improved electrical connector for use in forming an electrical connection between contact portions of two electrical substrates. The electrical connector comprises a connector body having a plurality of through holes, a plurality of electrical terminal pins floatably disposed within the through holes of the connector body. The terminal pins comprise piston-like heads that have a diameter slightly smaller than a diameter of the through holes.

According to another aspect of the invention, a crown is formed on a top surface of the through hole which forms an access opening to the through hole with a diameter smaller than the diameter of the through hole diameter. Moreover, the crown is preferably raised above a planar surface of the connector body so that the length of the through hole is effectively lengthened. The crown has a flexible quality so that the terminal pins can be inserted into the through holes and annular projections formed in the terminal pins can be pushed through the opening in the crown. Preferably, flexibility in the crown is gained by forming stress relief slits therein. Additionally, a flexible material may be used to form the crown, e.g., Kapton.

### DETAILED DESCRIPTION OF THE DRAWINGS

The foregoing summary, as well as the following detailed description of the preferred embodiments, is better understood when read in conjunction with the appended drawings. For the purpose of illustrating the invention, there is shown in the drawings an embodiment that is presently preferred, it being understood, however, that the invention is not limited to the specific methods and instrumentalities disclosed. In the drawings:

FIG. 1 is a top plan view of a connector which represents an exemplary embodiment of the connector of the present invention;

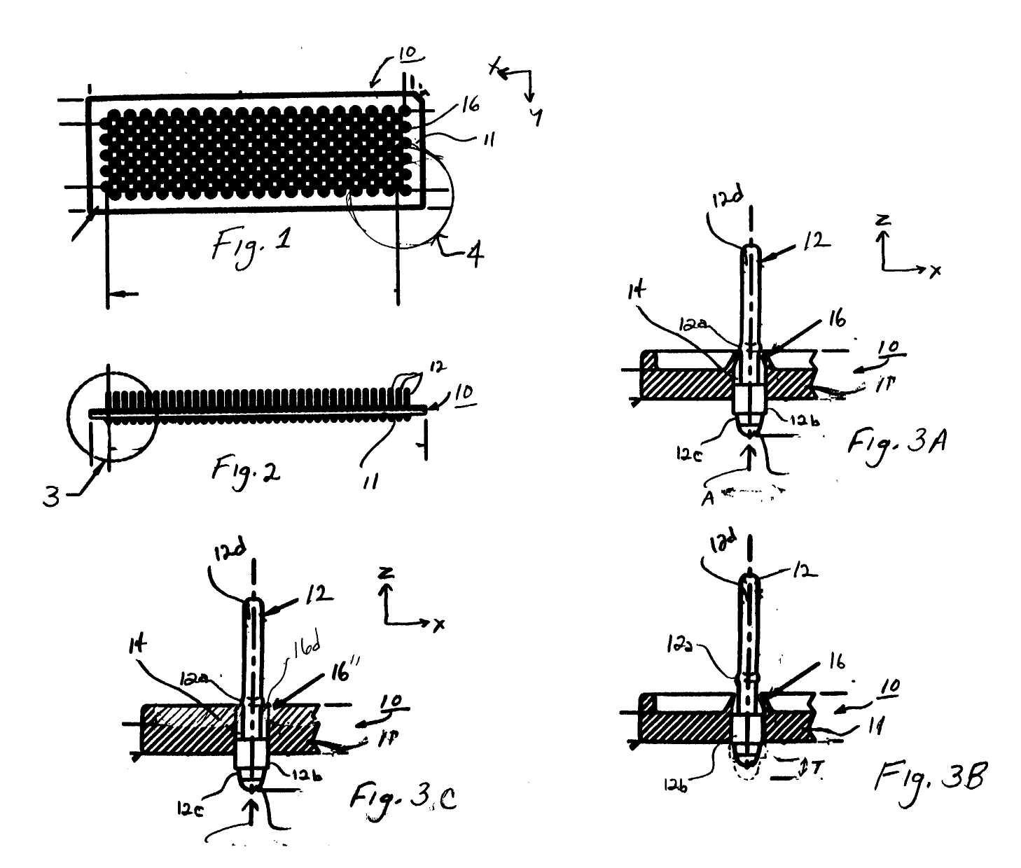

FIG. 2 is a side elevation view of the connector shown in FIG. 1;

FIGS. 3A and 3B are cross-sectional side views of the portion denoted 3 on the connector shown in FIG. 1;

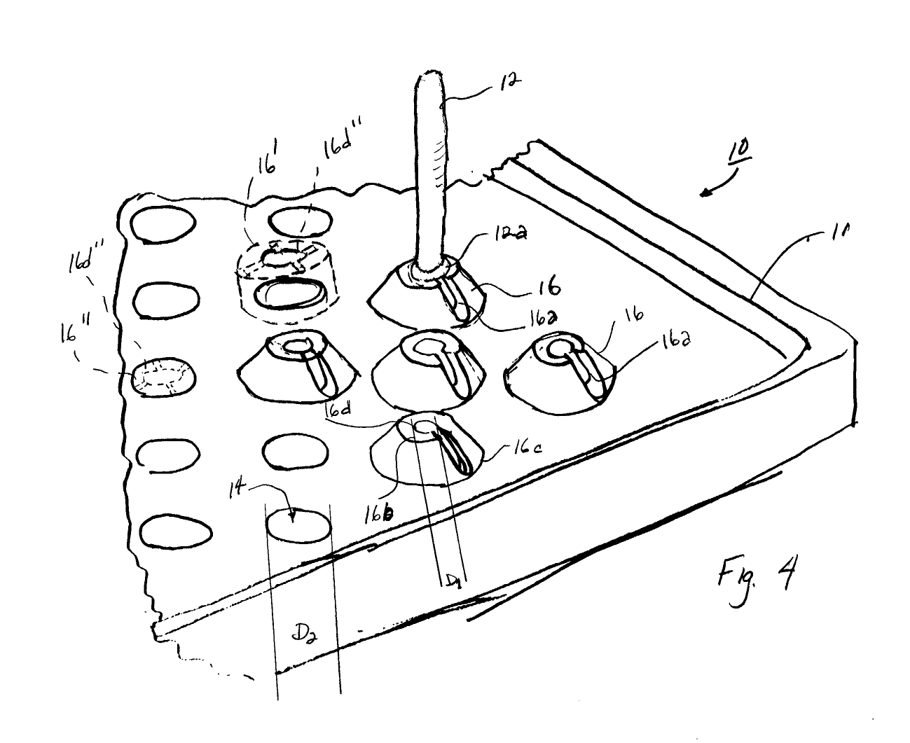

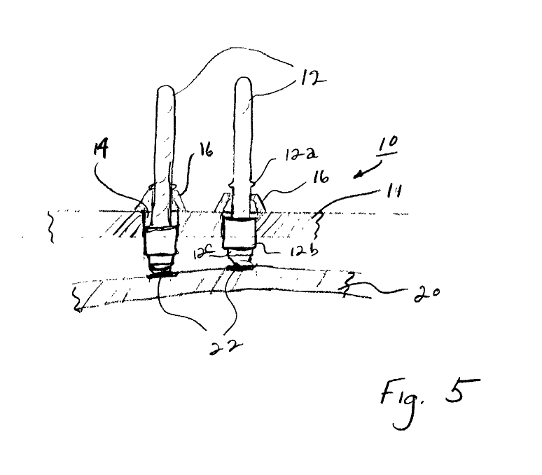

FIG. 4 is an isometric view of the portion denoted 4 in FIG. 1;

FIG. 5 is a cross-sectional side view of the connector of FIG. 1 illustrating the contact of terminal pins with a circuit substrate; and

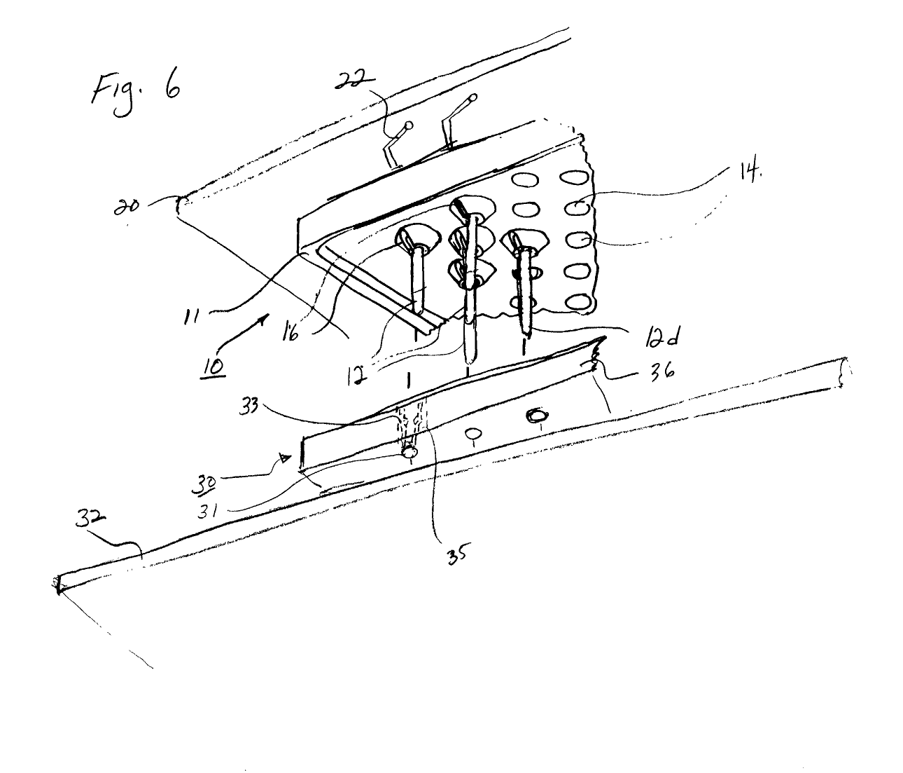

FIG. 6 is an isometric view of the connector of FIG. 1 bring two circuit substrates into electrical communication.

### DETAILED DESCRIPTION OF PREFERRED EMBODIMENTS

According to presently preferred embodiments, an electrical connector having floating electrical terminal pins will now be described with reference to the Figures. It will be appreciated by those of ordinary skill in the art that the description given herein with respect to those Figures is for exemplary purposes only and is not intended in any way to limit the scope of the invention. For example, an electrical connector is illustrated herein as having a particular dimensional shape and terminal pin count. However, the particular exemplary embodiment described herein with reference to that connector are merely for the purpose of illustration and are not intended to be limiting. The concepts disclosed herein have a broader application to a much wider variation of connector geometries.

Referring now to FIGS. 1-4 there is shown top, side and isometric views of an electrical connector 10 of the present invention. As shown, connector 10 comprises a substantially planar connector body 11, with a plurality of elongated conductors, i.e., terminal pins 12 floatably disposed therein. The connector body is preferably formed of a suitable insulative material and comprises a plurality of through holes extending through connector body 11.

As best shown in FIGS. 3A and 3B, the terminal pins 12 comprise an elongated main conductor body with a tail end 12d adapted to mate with and make electrical contact with a first electrical component or substrate (not shown in FIGS. 3A and 3B), a head 12b adapted for surface mounting to a second electrical substrate by way of solder 12c and a retaining projection 12a. To facilitate surface mounting of terminal pin 12, the pin preferably comprises a fusible electrical contact material 12c disposed on the end of terminal pin head 12b. The fusible material preferably comprises a material that is reflowable at conventional surface mounting temperatures, e.g., solder. More preferably, the fusible electrical contact comprises a solder ball that has been partially reflowed onto terminal pin head 12b according to, for example, ball grid array (BGA) techniques, or, for example, as described in U.S. patent application Ser. No. 08/851,165, filed May 2, 1997 and entitled “HIGH DENSITY CONNECTOR HAVING A BALL TYPE OF CONTACT SURFACE,” which is hereby incorporated by reference.

Each terminal pin 12 passes through connector body 11 by way of a through hole 14. Through holes 14 have a diameter sized to accommodate terminal head 12b to position pins 12 in the x and y axes while also allowing free movement of the terminal head within a through hole 14 in the z-axis. In other words, terminal head 12b has a slightly smaller diameter than through hole 14. In this way, terminal head 12b can move in piston-like fashion in the “z” direction with minimal resistance. At the same time, the walls of through hole 14 minimize movement of the terminal head 12b in the x and y directions.

A plurality of selected pin retention structures 16, 16′, or 16″ are coupled to the top planar surface of connector body 11. Pin retention structures 16, 16′, and 16″ can be formed as an aperture formed as a protuberance that projects from the top surface of connector body 11 (e.g., crowns 16 and 16′) or alternatively be formed essentially flush with the top surface of connector body 11 (e.g., reduced diameter portion 16″). As best shown in FIG. 4, the primary purpose of pin retention structures 16, 16′, and 16″ is to form a reduced aperture 16d (16d′, 16d″) that is concentrically aligned with diameter D2 of through hole 14 such that diameter D1 of the pin retention structures 16, 16′, 16″ is smaller than diameter D2 of through holes 14. In this way, the smaller diameter D1 accommodates the main body of terminal pin 12 and acts as a stop for z direction travel of terminal pin 12. At the same time, the larger diameter D2 of the through hole acts as a guide for the piston-like terminal head 12b.

Each crown 16, 16′ comprises a projection extending from the top surface of body 11 that includes a through hole that is substantially concentrically aligned through hole 14, providing a continuous conduit for terminal pins 12 to pass through both a through hole 14 and a crown 16, 16′. Preferably, the diameter of the top aperture 16b of crown 16, 16′ is about the same as the diameter of terminal pin 12 and sized so that terminal pin 12 can move in the z direction but not in the x and y directions.

The combination of crown 16 acting on the body of the terminal pin 12 and the through hole acting on the head 12b of terminal pin 12b act to provide stability to terminal pin 12 and prevent it from tilting. Additionally, because crown 16 preferably extends from the planar surface of the connector body 11, it effectively lengthens the through hole without requiring a connector body 11 of corresponding thickness. As a result, a more stable (i.e., free from tilting and so on) floating pin design is achieved in a relatively thin body 11. Since the through hole in crown 16, 16′ is tapered, terminal pin 12 can move within the through hole with less friction.

Pin retention structures 16, 16′, 16″ are preferably somewhat elastic and deformable. For example, as shown in FIG. 4, the present invention contemplates at least one slot 16a formed into the pin retention structures 16, 16′, 16″. Slot 16a reduces stress and allows deformation of the pin retention structure 16, 16′, 16″ as a projection 12a of terminal pin 12 passes through pin retention structure 16, 16′, 16″ during pin insertion while also inhibiting passage back through the pin retention structure 16, 16′, 16″. This deformation of pin retention structures 16, 16′, 16″ may also be aided by the selection of a suitably elastic material such as Kapton.

Preferably, crowns 16 are substantially truncated cones in shape; however, other suitable shapes could also be used such as cylindrical (see e.g., alternative crown 16′ shown in phantom in FIG. 4). Moreover, the crowns could be formed integrally with the main connector body 11 or formed separately and attached with conventional means such as by adhesive.

FIGS. 3A and 3B illustrate the float action of pin 12 in connector body 11. As described above, each pin comprises an elongated body with a head 12b and an annular projection 12a. FIG. 3A shows the terminal head 12b fully extended from the connector body 11. Here, the annular projection, which has an outer diameter larger than the top opening 16b of crown 16 prevents further outward travel of head 12b from through hole 14.

FIG. 3B shows the head 12b retracted into through hole 14. The retraction of head 12b is stopped as the head impinges on crown 16 from the other side of the opening 16b from the annular projection 12a. Thus, the terminal pin 12 has a range of travel within through hole 14 of a distance T. Despite the location of head 12b in through hole 14, pin 12 maintains true positioning in the x- and y-axes. Notably, the structure of terminal pin head 12b disposed within through hole 14 provides greater positioning accuracy of terminal pin 12 over conventional floating pin designs. Here, terminal pin head 12b has a wider diameter than the main body of terminal pin 12. As such, by using the relatively larger diameter of terminal pin head 12b provides advantageous positioning accuracy over a system using the main body of a terminal pin to provide x- and y-axes positioning.

FIG. 3C shows a cross section of an alternative embodiment of a connector body 11 wherein the pin retention structure 16″ is flush with the top surface of connector body 11. This view illustrates that a flush pin retention structure 16″ could be used where it is desirable to have a thicker connector body 11 or the presence of projections are undesirable. This is essentially the same embodiment as the pin retention structure 16″ of FIG. 4 except that here the thicker body 11 accommodates a longer through hole 14 that provides added stability to prevent terminal pin 16 from tilting.

Referring to FIG. 5, there is shown a cross-sectional portion of connector 10 having two terminal pins 12. Connector 10 is brought into contact with a conductive pad (not shown) on an electrical substrate 20, which may be a printed circuit board, an electrical component including, for example, an integrated circuit, or the like. Here, electrical substrate 20 is illustrated as having an irregular surface such as could be caused from warping, bending, or the like. Notably, terminal pins 12 have automatically adjusted themselves to the surface irregularities of substrate 20 by movement of head 12b in through hole 14. As such, both solder contact surfaces 12c have been brought into contact with the pads on electrical substrate 20, resulting in a more reliable electrical connection.

FIG. 6 illustrates the manner in which electrical connector 10 is employed to join two electrical substrates in electrical communication. Electrical substrate 20 has an electrical circuit associated with it and, for example, comprises electrical traces 22. During surface mounting of terminal pins 12 to electrical substrate 20, pin heads 12b are brought into electrical communication with, for example, pads associated with circuit traces 22 (see also FIG. 5). Fusible elements, e.g., solder balls, on the ends of terminal pin heads 12b are then reflowed to fixedly join the connector 10 to the electrical component 20. At this point, electrical component 20 and connector 10 form a PGA component, which can now be inserted into a conventional socket such as socket 30. Socket 30 can be any one of a number of PGA type sockets such as a socket for a central processing unit attached to a motherboard, e.g., board 32.

Hence by fixing connector 10 in electrical communication with substrate 20 and fixing mating connector 30 in electrical communication with substrate 32, substrates 20 and 32 can be brought into selective electrical communication by way of the connector system of connectors 10 and 30.

According to an aspect of the present invention, the connector provides manufacturing efficiencies. The connector body 11 is manufactured from a suitable laminate such as FR4 or a molded plastic sheet structure. The crowns 16 are attached proximate through holes 14, either by integral lamination or molding or by separate manufacture and adhesive. After the connector body 11 is formed with crowns 16, terminal pins 12 having annular projections 12a are inserted in through the bottom of connector body 11 in the direction indicated by arrow a in FIG. 3A. Terminal tails 12 pass though the though hole and through the crown. Annular projection 12a passes though opening 16b of crown 16. As noted, the crowns are designed to be suitably flexible so that the annular projections pass through the opening 16b with a predetermined application of insertion force. Preferably, slots 16a reduce the stress on crown 16 as annular projection 16a passes through during insertion. Thereafter, head 12b is inserted at least partially into and is maintained within through hole 14.

The resulting structure of through hole 14, and the extended through hole of pin retention structures 16, 16′, 16″ provide a length to diameter ratio that provides significant positioning stability of the terminal pin in the assembly. For example, head 12b of terminal pin 12 is inserted into through hole 14. Thus the though hole has a diameter that is somewhat independent of the diameter of the terminal pin. Head 12b then acts as a piston within the through hole ensuring a reliable head to electrical substrate interface while providing further stability due to its larger diameter relative to the terminal pin 12.

While the present invention has been described in connection with the preferred embodiments of the various figures, it is to be understood that other similar embodiments may be used or modifications and additions may be made to the described embodiment for performing the same function of the present invention without deviating therefrom. Therefore, the present invention should not be limited to any single embodiment, but rather construed in breadth and scope in accordance with the recitation of the appended claims.

What is claimed is:

1. An electrical connector comprising:
a connector body having a through hole formed therein;
a pin retention structure associated with said through hole, the pin retention structure restricting the diameter of the through hole; and
a terminal pin disposed within the through hole, the terminal pin having first and second projections disposed thereon, said first projection being disposed on one side of said pin retention structure and said second projection being disposed on the other side of said pin retention structure.

2. The electrical connector of claim 1, wherein said pin retention structure comprises an annular projection formed about and projecting inwardly toward a center axis of said through hole.

3. The electrical connector of claim 1 wherein said pin retention structure projects outwardly from a surface of said connector body.

4. The electrical connector as in claim 3, wherein the pin retention structure comprises a substantially conic shape.

5. The electrical connector as in claim 3, wherein the pin retention structure comprises a substantially cylindrical shape.

6. The electrical connector of claim 1, wherein the first projection comprises an annular projection.

7. The electrical connector as recited in claim 1 wherein said pin retention structure comprises a slot such that said pin retention structure is deformable as said first projection passes though it during insertion of a terminal pin.

8. The electrical connector as recited in claim 1, wherein the second projection comprises a surface mounting head disposed proximate one end of said terminal pin, the head comprising a diameter proximately the same size as a diameter of said through hole.

9. The electrical connector as recited in claim 1, wherein the second projection comprises an annular projection having a diameter sized to fit within said through hole.

10. The electrical connector as recited in claim 1, wherein the annular projection comprises a head that moves in piston-like fashion within at least a portion of said through hole.

11. An electrical component comprising:
a substantially planar insulative body having a plurality of through holes;
an pin retention structure disposed on said insulative body about said through holes, the pin retention structure forming an aperture at on end of said through hole having a diameter smaller than a diameter of said through hole;
a plurality of elongated conductive elements, each one of said conductive elements being disposed within said through holes and extending through said pin retention structures; and,
a first and second projection disposed on each of said plurality of elongated conductive elements, said first projection disposed one side of said pin retention structure and said second conductive element disposed on the other side of said pin retention structure.

12. An electrical component as in claim 11, wherein each said pin retention structure comprises a raised surface projecting from said planar insulative body.

13. An electrical component as in claim 12, wherein the raised surface of said pin retention structure is substantially conically shaped.

14. An electrical component as in claim 12, wherein the raised surface of said pin retention structure is substantially cylindrically shaped.

15. a method for aligning a connector terminal with a substrate, comprising the steps of:
a) providing a connector body with a through hole formed therein;
b) providing a pin retention structure having an annular opening with a diameter less than a diameter of the through hole; and
c) providing a terminal pin in said through hole with a projection sized that said projection provides a stop to travel of said terminal pin in said through hole whenever said projection impinges upon said pin retention structure.

16. The method as recited in claim 16 wherein said pin retention structure projects from a surface of said connector body.

17. The method as recited in claim 16 wherein said pin retention structure comprises a substantially conical shape.

18. The method as recited in claim 16, further comprising the step of providing a head on said terminal pin wherein said head comprises a diameter slightly less than a diameter of said through hole.

19. An electrical connector, comprising:
a connector body having a through hole formed therein;
a terminal pin having a piston-like head formed on one end thereof, the terminal pin being floatably inserted into said through hole so that at least a portion of said piston-like head is inserted into said through hole.

20. The electrical connector as recited in claim 19 further comprising a substantially annular crown coupled to said body in axial alignment with said through hole, wherein an end of said terminal pin passed through said crown.

21. The electrical connector as recited in claim 20 wherein said terminal pin further comprises a projection coupled thereto to constrain axial movement of said terminal pin in a first direction.

22. The electrical connector as recited in claim 21 wherein said projection comprises an annular projection.

23. The electrical connector as recited in claim 20 wherein said crown is formed to project axially from said connector body.

24. The electrical connector as recited in claim 23 wherein said crown comprises a conic shape.

25. The electrical connector as recited in claim 23 wherein said crown comprises a cylindrical shape.

26. A pin grid array kit comprising:
an electrical component having a plurality of conductive pads;
an insulative housing having a through hole formed therein;
a pin retention structure associated with said through hole, the pin retention structure restricting the diameter of the through hole; and
a terminal pin disposed within the through hole and engaged with said pad, the terminal pin having a first projection disposed on one side of said pin retention structure and a head being disposed on the other side of said pin retention structure, said head being at least partially disposed within said through hole, and said head having a diameter less than a diameter of said through hole.

27. The pin grid array kit as recited in claim 26 further comprising a second electrical component engaged with said terminal pin.

28. The pin grid array kit as recited in claim 26 wherein said electrical component includes an integrated circuit.

29. The pin grid array kit as recited in claim 27 wherein said second electrical component comprises a socket.

30. The pin grid array kit as recited in claim 26 further comprising a fusible material disposed on an end of said terminal head.

31. The pin grid array kit as recited in claim 26 wherein said pin retention structure is substantially flush with a planar surface of said insulative housing.

32. The pin grid array kit as recited in claim 26 wherein said pin retention structure projects from a surface of said insulative housing.

33. The pin grid array kit as recited in claim 32 wherein said pin retention structure comprises one of a conic and a cylindric shape.
